(19) United States
(12) Patent Application Publication
(10) Pub. No.: US 2011/0227103 A1
(43) Pub. Date: Sep. 22, 2011

(54) LED MODULE AND PRODUCTION METHOD

(75) Inventors: Georg Bogner, Lappersdorf (DE); Berthold Hahn, Hemau (DE); Siegfried Herrmann, Neukirchen (DE)

(73) Assignee: OSRAM OPTO SEMICONDUCTORS GmbH, Regensburg (DE)

(21) Appl. No.: 13/121,017

(22) PCT Filed: Aug. 26, 2009
(86) PCT No.: PCT/DE2009/001207

§ 371 Date: Jun. 2, 2011

(30) Foreign Application Priority Data
Sep. 29, 2008 (DE) 10 2008 049 535.2

(51) Int. Cl. H01L 27/15; H01L 33/62; H01L 33/48; H01L 33/00

(52) U.S. Cl. 257/89; 257/99; 438/28; 438/26; 257/E27.12; 257/E33.066; 257/E33.056; 257/E33.001

(57) ABSTRACT

An LED module includes a layer stack of a substrateless LED, an emission area of the layer stack, the emission area being provided for light emission, a substrate having a top side on which the substrateless LED is arranged, contact areas arranged at a side area of the substrate, wherein the side area is perpendicular to the emission area, and/or including a base body which has contact areas at a side area and on which the substrate is mounted in such a way that the side area is perpendicular to the emission area, a first connection line between the LED and one of the contact area, and a second connection line between the LED and another of the contact areas.

### RELATED APPLICATIONS

This is a §371 of International Application No. PCT/DE2009/001207, with an international filing date of Aug. 26, 2009 (WO 2010/034277 A1, published Apr. 1, 2010), which is based on German Patent Application No. 10 2008 049 535.2, filed Sep. 29, 2008, the subject matter of which is incorporated by reference.

### TECHNICAL FIELD

This disclosure relates to an LED module which can be configured in a particularly flat fashion, and to an associated production method.

### BACKGROUND

A method for producing a plurality of optoelectronic components is disclosed in DE 10 2007 030 129. A connection carrier assemblage is provided, which has a plurality of component regions, in each of which is provided at least one electrical connection region, and also a semiconductor body carrier, on which a plurality of separate semiconductor bodies connected to the semiconductor body carrier are arranged, wherein the semiconductor bodies each have a semiconductor layer sequence having an active region. The connection carrier assemblage and the semiconductor body carrier are oriented relative to one another in such a way that the semi-conductor bodies face the component regions. A plurality of semiconductor bodies are mechanically connected to the connection carrier assemblage in a mounting region of a component region assigned to the respective semiconductor body, and the respective semiconductor body is electrically conductively connected to the connection region of the component region assigned to the semiconductor body. The semiconductor body connected to the connection carrier assemblage is separated from the semiconductor body carrier, and the connection carrier assemblage is separated into a plurality of separate optoelectronic components each having a connection carrier having the component region, and a semiconductor body that is arranged on the connection carrier and is electrically conductively connected to the connection region.

Particularly compact and flat arrangements of LEDs with a large emission area are required for various applications such as the backlighting of monitors, for example.

It could therefore be helpful to provide a particularly flat LED module which can be produced simply and cost-effectively. Moreover, it could also be helpful to provide a production method suitable therefor.

### SUMMARY

We provide an LED module including a layer stack of a substrateless LED, an emission area of the layer stack, the emission area being provided for light emission, a substrate having a top side on which the substrateless LED is arranged, contact areas arranged at a side area of the substrate, wherein the side area is perpendicular to the emission area, and/or including a base body which has contact areas at a side area and on which the substrate is mounted in such a way that the side area is perpendicular to the emission area, a first connection line between the LED and one of the contact areas, and a second connection line between the LED and another of the contact areas.

We also provide a method for producing an LED module including mounting substrateless LEDs having electrical connections on a top side of a wafer, producing openings with walls in the wafer, arranging electrical conductors on the walls, electrically conductively connecting the electrical conductors to the connections of the LEDs by connection lines arranged on the top side of the wafer, and dividing the wafer into substrates in such a way that the substrates have side areas which adjoin the top side and on which the electrical conductors are arranged.

We further provide a method for producing an LED module including arranging a layer stack of a substrateless LED with an emission area provided for light emission on a top side of a substrate, providing the substrate with electrically conductive connections between connections of the LED and contact areas at a rear side lying opposite the top side, and mounting the substrate by the rear side on a base body which is provided with contact areas and connection conductors such that contact areas are situated at a side area of the base body that is present perpendicularly to the emission area, and are electrically conductively connected to the contact areas of the substrate by the connection conductors.

### BRIEF DESCRIPTION OF THE DRAWINGS

FIG. 1 shows a perspective view of an individual design of the LED module with a substrateless LED on a substrate.

FIG. 2 shows an alternative configuration of an individual design in a plan view.

FIG. 3 shows a plan view of a matrix-like arrangement of LEDs on a wafer.

FIG. 4 shows an excerpt from a wafer row.

FIG. 5 shows an arrangement in accordance with FIG. 4 in a side view.

FIG. 6 shows a perspective view of an example of an LED module mounted on a board.

FIG. 7 shows a perspective view of a further example of an LED module mounted on a board.

FIG. 8 shows a plan view of the top side of a further example of the LED module.

FIG. 9 shows a plan view of the rear side of the example from FIG. 8.

FIG. 10 shows a plan view in accordance with FIG. 8 of the top side of a further example of the LED module.

FIG. 11 shows a perspective view of a base body.

FIG. 12 shows, in a manner corresponding to FIG. 11, a perspective view of the base body with an LED module mounted thereon.

### DETAILED DESCRIPTION

The LED module comprises at least one substrateless LED arranged as a layer stack on a top side of a substrate.

The substrateless LED is, for example, a light-emitting diode chip from whose epitaxially grown layers the growth substrate has been completely removed. The substrateless light-emitting diode therefore comprises, for example, exclusively epitaxially grown semiconductor layers. It can have a thickness of at most 20 μm. The substrateless LED can also on account of its small thickness be transmissive to visible light.

At at least one side area adjoining the top side, the substrate has contact areas for an external electrical connection of the LED. The connections of the LED connect to the associated contact areas with conductor tracks provided on the top side. The LED module can also comprise a plurality of LEDs. In this case, a plurality of layer stacks of substrateless LEDs are arranged on the top side of the substrate and connected to a corresponding plurality of contact areas provided on a side area. The contact areas can be conductor tracks structured in strip form on the side area. The contact areas can also be formed by electrically conductive, preferably metallized, soldering fillets at the edges of the side area which are perpendicular to the top side.

Soldering fillets of this type can be produced while the substrate is situated together with further substrates in the assemblage of a larger starting substrate, designated hereinafter as “wafer.” That is preferably done by producing contact holes in the wafer, electrically conductive material being introduced into the contact holes in the manner of plated-through holes (vias). The electrically conductive material can fill the contact holes or else cover only the sidewalls thereof. The use of a metal and the formation of metal on the sidewalls of the contact holes is preferred in this case. The wafer is then divided, the vias being cut such that soldering fillets with metal layers in the form of quarter hollow cylinders or half hollow cylinders arise from cylindrical vias.

The LED module is provided for mounting wherein the side area provided with the contact areas is fitted on a carrier, for example, a circuit board or a board (PCB, printed circuit board), and the contact areas electrically conductively connect to associated electrical connections of the carrier. If a plurality of LEDs, for example, in one or a plurality of series, are arranged on a substrate of corresponding dimensions, the LED module can be designed for large-area light emission and adapted to different applications. Mounting on the side area makes it possible, in particular, for the top side provided for the emission of light to be kept very narrow and, thus, for an extremely flat LED module to be realized.

The LED module is produced from substrateless LEDs, preferably in the front end by wafer level technology. For this purpose, a multiplicity of individual layer stacks for LEDs are applied to a top side of a wafer in a matrix-like arrangement. In this arrangement it is possible to provide in each case individual series of layer stacks or else in each case a plurality of successive series of layer stacks for an LED module, and each LED module to be produced comprises a corresponding multiplicity of individual LEDs. Instead, it is also possible in this way to produce individual components comprising only one LED. The distance between the layer stacks of the LEDs is chosen such that the substrate can be separated by customary processes such as sawing, laser separation or breaking The distance can typically be, e.g., approximately 30 μm to 200 μm.

Conductor tracks that contact the LEDs and connect the connections of the LEDs to the lateral contact areas are produced by photolithography on the wafer. The contact areas for the external electrical connections can be produced by contact hole fillings in those regions in which the wafer is intended to be divided into the substrates of the individual LED modules. During the division of the wafer into LED modules, each comprising one or a plurality of LEDs, the plated-through holes produced in the contact holes are divided and in each case produce at least one contact area, for example, in the form of a soldering fillet. Instead of contact hole fillings, the contact areas can also be produced, for example, by trenches milled into the wafer, the sidewalls of which trenches subsequently form the sidewalls of the individual substrates to be produced. A structure of conductor tracks is produced on these sidewalls by a method known per se, which conductor tracks form the contact areas and are connected to the associated conductor tracks on the top side of the wafer.

Owing to the absence of housing walls, it is possible, as early as in the wafer assemblage, to apply chip coverings such as silicones or the like as thin layers or films. When white LEDs are used, the conversion can be effected by chip level coating by application of conversion laminae or films or by overmolding.

The configurations described make it possible to produce extremely flat laterally emitting LED modules, the lateral dimensioning of which corresponds to the sum of the width of the layer stack of the LED and the width of the separating trench. The required dimensioning and the emission power can be defined by the geometry of the LED. Since the LED is a surface emitter and does not have its own semiconductor chip substrate, and in addition conventional wire bonding and also housing walls are absent in the device and the LED is not seated in a pot that is potted in a plane fashion, for example, the substrate is therefore free of cavities, virtually no light emitted by the LED is reflected or absorbed. Moreover, in the case where the light is coupled in laterally, the LED module can be positioned very close to an optical waveguide. If, by the method described, not only one substrateless LED in each case is applied on the substrate, rather a plurality of LEDs are produced one above another as a layer stack, it is possible to produce multicolored LED modules, e.g., red, green and blue with extremely small dimensions. Consequently, during the coupling into the optical waveguide, virtually no mixing region and a very homogeneous color image arise.

Since the customary plastic housing is absent, the height of the LED module can be significantly reduced. A customary plane potting is not necessary, as a result of which backscattering and absorption losses are considerably reduced. Mounting tolerances are minimized by the specific production method. The dimensions of the LED are substantially determined by the layer stack, for which reason, even in the case of miniature designs, it is possible to maximize the chip area used and, hence, the efficiency of the component. Typical applications of the LED module are, e.g., backlighting for a mobile phone keypad, display backlighting for LCD displays and RGB or other color and conversion compositions.

When a substrate having a small height is used, the LED module can be mounted on a base body having larger dimensions, which facilitates handling, in particular for orienting the emission area perpendicularly to a support.

The substrate can contain additional functions such as a protective diode, for example. In this way, the substrate can form a functional base body in which a protective diode can be monolithically integrated, in particular, for example, in a substrate composed of silicon having differently doped regions, wherein the characteristic curve of the protective diode is set by the distance and position of the metal contacts.

In accordance with at least one example of the LED module described here, the mounting area of the substrate and/or of the base body, on which mounting area the substrateless LED is arranged, is free of cavities. That is to say that the substrateless LED is not arranged in a cavity.

In accordance with at least one example, the LED module comprises a contact ramp on which a connection line for making contact with the substrateless LED is arranged. The contact ramp comprises an oblique surface that overcomes the difference in height prescribed by the substrate. The contact ramp is formed from an electrically insulating material, for example. The contact ramp can have the form of a wedge, for example.

A production method for producing an LED module is furthermore specified. By way of example, an LED module described here can be produced in this case. That is to say that all the features disclosed for the LED module are also disclosed for the method, and vice versa.

In accordance with at least one example, the method is a production method wherein
substrateless LEDs having the electrical connections are mounted on a top side of a wafer,
openings with walls are produced in the wafer,
electrical conductors are arranged on the walls,
the electrical conductors are electrically conductively connected to the connections of the LEDs by connection lines arranged on the top side of the wafer, and
the wafer is divided into substrates in such a way that the substrates have side areas which adjoin the top side and on which the electrical conductors are arranged.

Examples of the LED module and of the production method will be described in greater detail below with reference to the accompanying figures.

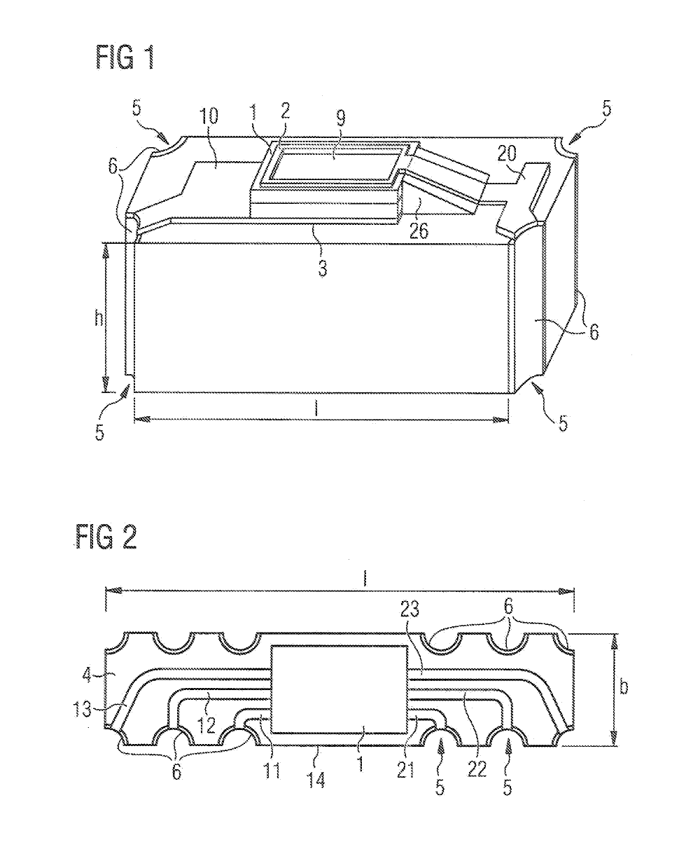

FIG. 1 shows a perspective view of an individual design of the LED module with a substrateless LED on a substrate with lateral contact areas. The LED comprises a layer stack 1, which is not arranged on a semiconductor substrate, for which reason the LED is designated as a substrateless LED. The layer stack 1 is provided with an upper connection contact 2 and with a lower connection contact 3. The upper connection contact 2 is formed from a material that is transmissive to the light to be emitted, or is formed in a frame-shaped manner, as in the example illustrated in FIG. 1 such that the emission area 9 remains free. This arrangement is situated on a substrate 4, which can be, for example, a ceramic material, silicon or some other insulator. The soldering fillets 5 are situated at the edges of the substrate 4 which are vertical with respect to the top side provided with the layer stack 1, which soldering fillets, in the example illustrated, are in each case provided with conductor layers 6, preferably with metal layers, in the form of a quarter hollow cylinder. The conductor layers 6 form the contact areas provided for the external electrical connection of the LED module on the relevant side area 14 of the substrate.

Soldering fillets of this type can be produced, for example, by contact holes being produced in a starting substrate (wafer) and subsequently being filled with electrically conductive material, preferably a metal. In this case, it suffices if the electrically conductive material forms a thin conductor layer only at the walls of the contact holes. After the wafer has been divided into the substrates 4 of the LED modules, the cutouts discernible in FIG. 1 in the form of a quarter cylinder with the thin conductor layers 6 present thereon respectively remain at the edges provided with the contact hole fillings.

By contrast, if the contact holes had been completely filled with the electrically conductive material, the soldering fillets 5 illustrated in FIG. 1, after the division of the wafer, are filled with electrically conductive material in the form of a quarter cylinder such that the substrate 4 is parallelepipedal through to the lateral edges.

For the electrically conductive connection between the lower connection contact 3 and the associated lateral contact area provision is made of a first connection line 10, and for the electrically conductive connection between the upper connection contact 2 and the associated lateral contact area provision is made of a second connection line 20, which, in this example, is led by way of a contact ramp 26, preferably composed of a patternable insulation material customary in semiconductor technology. The height h of the substrate as depicted in FIG. 1 can typically be approximately 0.2 mm to 1.0 mm. The length l of the individual component can typically be approximately 300 μm to 3 mm. With those conductor layers 6 which are connected to the connection lines 10, 20, the LED module can be soldered on a circuit board or the like, electrically conductive connections to corresponding conductor tracks of the circuit board being produced. The top side of the layer stack 1, the top side being provided for the light emission, can be provided, in particular, with a converter covering or similar device for modifying the light emission.

FIG. 2 shows a further example of an individual design of the LED module in a plan view of the top side of the substrate 4, the top side being provided with a layer stack 1 of the LED. The width b of the substrate as depicted in FIG. 2 can typically be approximately 50 μm to 1 mm. In contrast to the example in FIG. 1, in the case of the example in FIG. 2, a plurality of soldering fillets 5 are present on a side area of the substrate 4. The conductor layers 6 of the soldering fillets 5 therefore permit a plurality of connection lines to be connected. That enables an example which is provided for light emission of different colors, in particular red, green and blue (RGB example). For this purpose, layers for the different colors are provided in the layer stack 1, preferably by separately grown epitaxial layers for the different colors being mounted one above another. These layers are in each case provided with an upper connection contact and a lower connection contact, and these connection contacts are conductively connected, by the connection lines depicted in FIG. 2, to respective contact areas formed by the conductor layers 6 in the soldering fillets 5.

For the electrical connection of the layer provided for the first color, a first connection line 11 and a second connection line 21 are provided, which, in the example illustrated, are led to those soldering fillets which are arranged closest to the layer stack 1. For the connection of the layer provided for the second color, a further first connection line 12 and a further second connection line 22 are correspondingly provided, and for the connection of the layer provided for the third color, a further first connection line 13 and a further second connection line 23 are likewise provided.

The arrangement of the respective connection lines is illustrated here only as an example and can be varied in accordance with the respective requirements. In particular, it is possible for the connection lines to be connected in each case to those contact areas which are arranged above the associated connections of the circuit board. The connection lines of the LEDs can be led, e.g., using multilayer ceramic in a manner known per se in different planes of the substrate to the soldering pads of the circuit board.

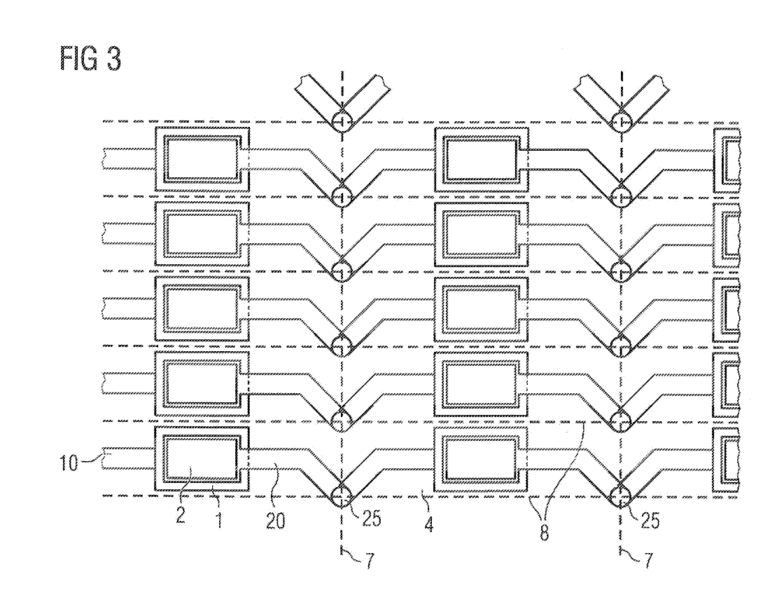

FIG. 3 shows a plan view of a top side of a wafer with layer stacks 1 of LEDs in a row-wise and column-wise arrangement. In the case of the example in FIG. 3, a first connection line 10 and a second connection line 20 are provided for each LED. Instead, a multilayered layer structure in accordance with the example in FIG. 2 can be provided for each LED. The connection lines 10, 20 are led in each case to an associated plated-through hole 25. The plated-through holes 25 can be produced by contact holes being produced in the wafer and being at least partly filled with an electrically conductive material.

The plan view illustrated in FIG. 3 depicts a first set 7 of parallel cutting lines and a second set 8 of parallel cutting lines running perpendicularly thereto. If the wafer is not divided completely into individual designs of the LED module, but rather only along the first set 7 or the second set 8 of cutting lines, this results in LED modules on strip-like elongate substrates having a plurality of LEDs, which can be used as laterally emitting LED modules. By dividing the wafer along the first set 7 of cutting lines, this results in an arrangement in which the individual LEDs are arranged adjacent to one another by the longitudinal sides of their layer stacks 1.

The wafer strip forming the LED module is therefore shorter than in the case where the wafer is subdivided along the second set 8 of cutting lines. LED modules having LEDs arranged successively in both directions can also be produced by the wafer not being divided along all the cutting lines of a set 7, 8, but rather only at larger intervals.

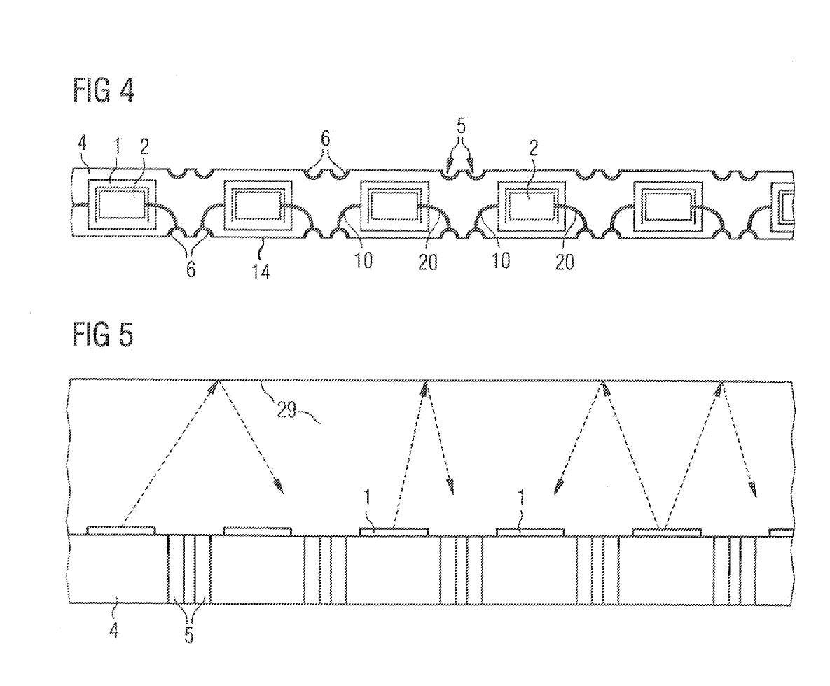

If the arrangement in accordance with FIG. 3 is divided along the second set 8 of parallel cutting lines, this results in strip-shaped LED modules which, in plan view, approximately correspond to the example illustrated in FIG. 4.

FIG. 4 shows an example in which a separate lateral contact area with a conductor layer 6 is present for each connection line of each LED. The respective first connection line 10 of an LED and the respective second connection line 20 of the LED adjacent thereto are therefore electrically isolated from one another and can be connected in a manner isolated from one another, e.g., on a circuit board. That enables the individual LEDs to be driven separately.

FIG. 5 shows the LED module in accordance with FIG. 4 in a lateral view. The substrate 4 and the vertical soldering fillets 5 are illustrated in FIG. 5. The layer stacks 1 are situated on the top side of the substrate 4, the layer stacks being covered by a light distribution plate 29 in this example. The light distribution plate 29 uniformly distributes the light emitted by the LEDs, thus resulting in a homogeneous light emission wherein the LEDs are not or hardly perceptible as individual light sources. In this way, it is possible to achieve a large-area homogeneous light emission with an LED module which has a small structural height and can be embodied as a very narrow strip as necessary.

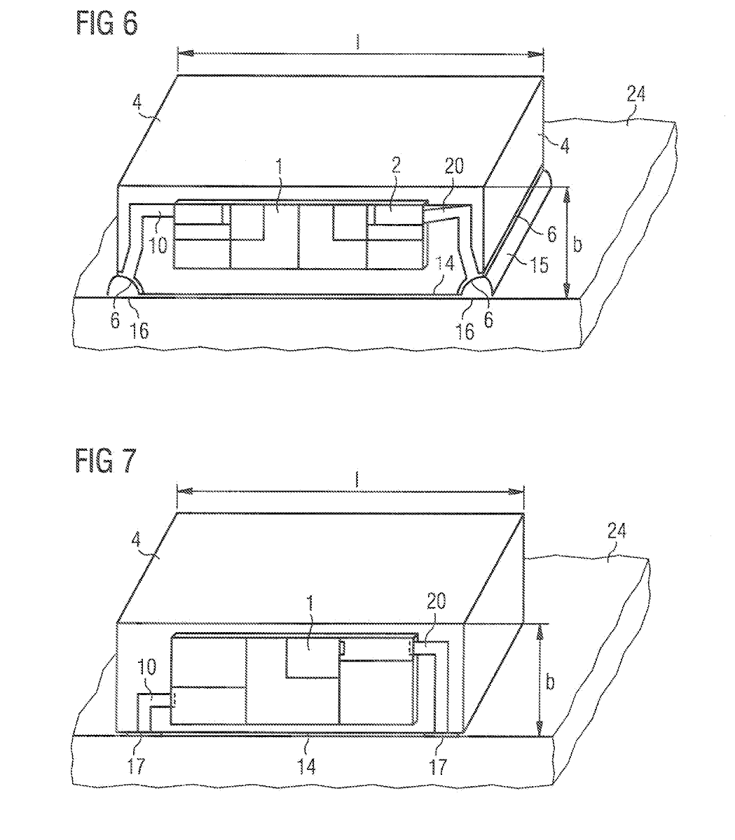

FIG. 6 shows how an LED module, which is again illustrated as an individual design in the example shown, can be mounted on a board 24. For the electrical connection to conductors which are present on and, if appropriate, in the board 24 in a manner known per se and are not illustrated, a solder 15 is used, which, in the solder fillets, produces an electrical connection between solder contacts 16 on the conductors of the board 24 and the conductor layers 6 and thus the connection lines 10, 20. As can be discerned in FIG. 6, the light emission is effected from the plane of the emission area of the layer stack 1 which is perpendicular to the top side of the board 24. In other words, the light is emitted in a lateral direction with respect to the board 24.

FIG. 7 shows a view in accordance with FIG. 6 for a further example. In this case, no soldering fillets are provided at the LED module. Instead, conductor strips which form the contact areas and are connected to the connection lines 10, 20 are situated on that side area of the substrate 4 which faces the board 24. The contact areas can be produced, for example, by trenches being produced in a wafer and their sidewalls being provided with conductor tracks. After the wafer has been divided, one region of such a sidewall forms that side area of the substrate 4 which faces the board 24 after the mounting of a LED module. A solder 17, which can be applied to the board 24 with a screen printing method, for example, connects the respective contact area of the substrate 4 to an associated conductor of the board 24.

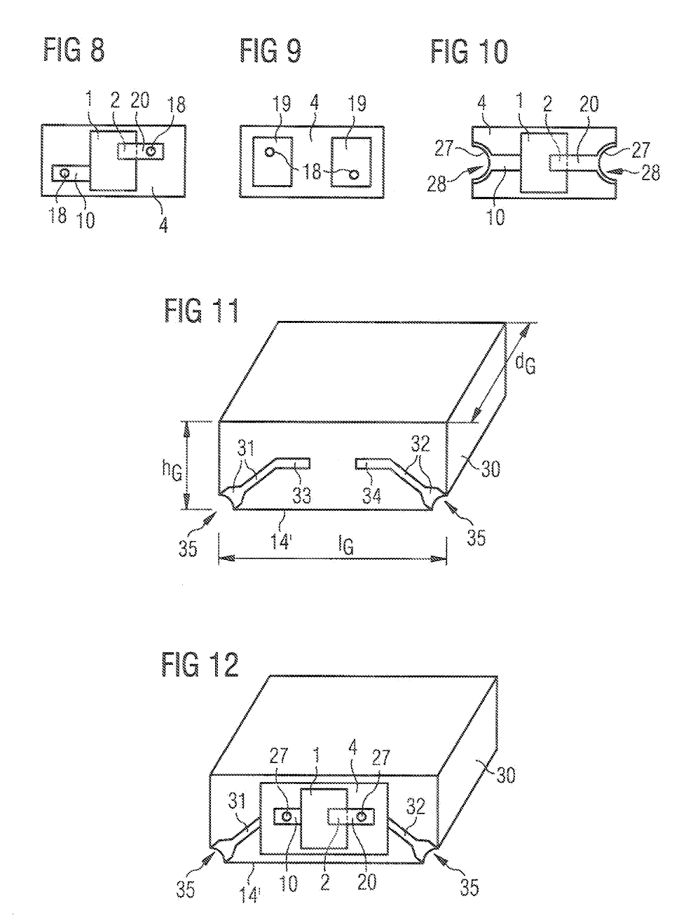

FIG. 8 shows a plan view of the top side of a further example of the LED module, wherein the layer stack 1, as in the example in FIG. 1, is arranged on a substrate 4 and provided with a first connection line 10 and a second connection line 20. In this case, however, the connection lines 10, 20 are not led to the edge of the substrate, but rather are provided with plated-through holes 18 through the substrate 4. The plated-through holes 18 form electrically conductive connections between the connection lines 10, 20 and rear side contacts of the substrate. The positions of the plated-through holes 18 are depicted for clarification purposes in FIG. 8, even though they are not necessarily discernible below the connection lines 10, 20.

FIG. 9 shows a plan view of the rear side, lying opposite the top side, of the example in FIG. 8. Rear side contacts 19 are applied on the rear side, the rear side contacts being connected to the plated-through holes 18 and in this way enabling a rear-side electrical connection of the LED. The positions of the plated-through holes 18 are depicted for clarification purposes in FIG. 9, even though they are not necessarily discernible below the rear side contacts 19.

FIG. 10 shows a plan view in accordance with FIG. 8 of the top side of a further example of the LED module, wherein the connection lines 10, 20 are led to the side areas of the substrate 4 and connected there to conductor layers 27 on sidewalls of plated-through holes 28. The plated-through holes 28 can be produced in accordance with the method described with reference to FIG. 3, by contact holes being etched into a wafer at the positions provided for the plated-through holes and an electrically conductive material being applied at least to the sidewalls of the contact holes. The wafer is then divided in such a way that the plated-through holes are severed only in one direction, such that the conductor layers 27 are situated in a manner adjoining the side areas of the individual components in semicylindrical cutouts, for example, as can be discerned in FIG. 10. Rear side contacts as in the example in FIG. 9 can be present on the rear side, the rear side contacts being connected to the conductor layers 27 on the side areas by connection conductors. However, the rear side contacts 19 of the substrate 4 can be dispensed with if contact areas of the LED module in accordance with FIG. 10 are arranged in the form of conductor layers on side areas of the substrate 4.

FIG. 11 shows a base body 30 in a perspective plan view. In the example illustrated, the base body 30 is parallelepipedal, but this is not necessary. The base body 30 is provided with a first connection line 31 and a second connection line 32 on one surface. The connection lines 31, 32 respectively have a contact area 33, 34 arranged on the surface. The contact areas 33, 34 are respectively electrically conductively connected by means of the connection lines 31, 32 to contact areas present at a side area 14′ of the base body. In the example illustrated, the contact areas of the side area 14′ are formed by metallized soldering fillets 35 situated at edges of the base body 30 which delimit the side area 14′. The base body 30 is provided for mounting of the LED module, for example, in one of the examples in FIGS. 8 to 10.

That surface of the base body 30 which is provided with the connection lines 31, 32 can have a length lG measured parallel to the side area 14′ of typically approximately 1 mm to 3 mm. The base body 30 can have a depth dG measured perpendicularly to the surface of typically approximately 0.5 mm to 2 mm and a height hG measured perpendicularly to the side area 14′ of typically approximately 0.2 mm to 2 mm. If such a base body 30 is used, an LED module comprising a substrate 4 having a small height h (FIG. 1) of typically approximately 100 μm to 400 μm can also be mounted in a simple manner, even in the case of a small width b (FIG. 2) of the individual component of typically approximately 50 μm to 100 μm.

The LED module can be mounted on the base body 30 in accordance with the illustration in FIG. 12. The rear side contacts 19 are electrically conductively connected to the contact areas 33, 34 with a conventional soldering or adhesive-bonding method, for example, such that the first connection line 10 of the LED module is connected to the first contact area 33 and the second connection line 20 is connected to the second contact area 34 by the conductors of the plated-through holes 18, 28.

A corresponding procedure is adopted in the case of the example in accordance with FIG. 10 if no rear side contacts are provided, the connection lines of the base body 30 being embodied in such a way that they enable a lateral contact-connection of the LED module. Consequently, by the first connection line 31 and the second connection line 32 of the base body 30 there are electrically conductive connections between the connections of the LED and the metallizations of the soldering fillets 35 of the base body 30.

The base body 30 can then be mounted instead of the substrate 4 in the example in FIG. 6 in a corresponding manner on an arbitrary board 24. The use of the base body facilitates the handling of the LED module despite the thin substrate owing to the larger dimensions of the base body in comparison therewith.

In the case of the example in FIG. 12, a solder is introduced into the soldering fillets 35 of the base body 30 to produce the electrical connections to conductors of the board 24. Instead, the base body 30 can be configured in a manner similar to the substrate 4 illustrated in FIG. 7 such that the tracks composed of solder 17, which are applied by means of a screen printing method, for example, produce the connection between the contact areas on the side area 14′ of the base body 30 and the assigned contact areas of the board 24.

The base body, in the same way as the substrate, can contain additional functions such as, for example, a protective diode or a zener diode. The relevant component can be monolithically integrated in the base body, in particular, for example, in a base body composed of silicon.

This disclosure is not restricted to the examples by the description on the basis thereof. Rather, the disclosure encompasses any novel feature, but also any combination of features, which in particular includes any combination of features in the appended claims, even if this feature or this combination itself is not explicitly specified in the claims or examples.

1. An LED module comprising:
a layer stack of a substrateless LED,
an emission area of the layer stack, the emission area being provided for light emission,
a substrate having a top side on which the substrateless LED is arranged,
contact areas arranged at a side area of the substrate, wherein the side area is perpendicular to the emission area, and/or comprising a base body which has contact areas at a side area and on which the substrate is mounted in such a way that the side area perpendicular to the emission area,
a first connection line between the LED and one of the contact areas, and
a second connection line between the LED and another of the contact areas.

2. The LED module according to claim 1, wherein
the layer stack comprises layers that generate light having different colors, and
two connection lines at the LED for each color, the connection lines connected to mutually separate contact areas.

3. The LED module according to claim 1, comprising:
a plurality of substrateless LEDs arranged on the top side of the substrate, and
a plurality of contact areas arranged at the side area of the substrate and/or at a side area of a base body on which the substrate is mounted, and are connected to associated connection lines of the LEDs.

4. The LED module according to claim 1, wherein the LEDs are arranged on the top side of the substrate in a single series.

5. The LED module according to claim 1, wherein the contact areas connected to connection lines are conductor tracks oriented vertically with respect to the top side.

6. The LED module according to claim 1, wherein at least some of the contact areas are arranged in soldering fillets and are in each case formed by a thin conductor layer in the form of a quarter hollow cylinder.

7. The LED module according to claim 1, wherein the substrate or the base body with the side area is arranged on a board provided with electrical connections.

8. The LED module according to claim 1, wherein the base body is a parallelepipedal base body having a top side provided with the substrate and a side area provided with contact areas,
the substrate has a height (h) of 100 μm to 400 μm measured perpendicularly to the top side,
the top side of the base body has a length (lG) of 1 mm to 3 mm measured parallel to the side area (14′), and
the base body has a height (hG) of typically approximately 0.2 mm to 2 mm measured perpendicularly to the side area (14′) and a depth (dG) of 0.5 mm to 2 mm measured perpendicularly to the top side.

9. A method for producing an LED module comprising:
mounting substrateless LEDs having electrical connections on a top side of a wafer,
producing openings with walls in the wafer,
arranging electrical conductors on the walls,
electrically conductively connecting the electrical conductors to the connections of the LEDs by connection lines arranged on the top side of the wafer, and
dividing the wafer into substrates in such a way that the substrates have side areas which adjoin the top side and on which the electrical conductors are arranged.

10. The method according to claim 9, wherein
the electrical conductors are produced in the openings in the wafer in the manner of plated-through holes,
the connection lines are produced between the LEDs and the plated-through holes, and
the wafer is divided into substrates such that the plated-through holes form soldering fillets provided with electrical conductors.

11. The method according to claim 10, wherein
the plated-through holes are produced by contact holes formed in the wafer and thin conductor layers applied to walls of the contact holes.

12. The method according to claim 10, wherein
the wafer is divided into substrates such that the soldering fillets are situated at edges of the substrates which in each case ran perpendicularly to the top side provided with the LEDs.

13. The method according to claim 9, wherein
to produce the openings, trenches having sidewalls are formed in the wafer,
conductor tracks running vertically with respect to the top side of the wafer are formed on the sidewalls,
the connection lines are produced between the LEDs and the conductor tracks, and
the wafer is divided into substrates in such a way that the substrates have side areas which adjoin the top side and on which the conductor or tracks formed on the sidewalls of the trenches are arranged.

14. The method according to claim 9, wherein
in each case only electrical conductors which are arranged on the same side area of a substrate are connected to the connection lines.

15. A method for producing an LED module comprising:
arranging a layer stack of a substrateless LED with an emission area provided for light emission on a top side of a substrate,
providing the substrate with electrically conductive connections between connections of the LED and contact areas at a rear side lying opposite the top side, and
mounting the substrate by the rear side on a base body which is provided with contact areas and connection conductors such that contact areas are situated at a side area of the base body that is present perpendicularly to the emission area, and are electrically conductively connected to the contact areas of the substrate by the connection conductors.
